(19) United States
(12) Patent Application Publication
(10) Pub. No.: US 2025/0183229 A1
(43) Pub. Date: Jun. 5, 2025

(54) BYPASS CHIPLETS FOR MEMORY-LOGIC STACK

(71) Applicant: Advanced Micro Devices, Inc., Santa Clara, CA (US)

(72) Inventor: Gabriel LOH, Bellevue, WA (US)

(21) Appl. No.: 18/540,257

(22) Filed: Dec. 14, 2023

Related U.S. Application Data
(63) Continuation of application No. 18/526,298, filed on Dec. 1, 2023, now abandoned.

(51) Int. Cl. H01L 25/065; H01L 23/00; H01L 23/367; H01L 23/498; H10B 80/00

(52) U.S. Cl. CPC H01L 25/0657; H01L 23/3672; H01L 23/49838; H01L 24/16; H01L 24/32; H01L 24/73; H01L 2224/16146; H01L 2224/16225; H01L 2224/32146; H01L 2224/32225; H01L 2224/73204; H01L 2225/06513; H01L 2225/06544; H01L 2225/06562; H01L 2924/1431; H01L 2924/1436; H10B 80/00

(57) ABSTRACT

An integrated circuit (IC) layer stack is disclosed that integrates bypass chiplets in the IC layer stack without requiring fabrication of through-silicon vias (TSV) in a digital device for signals and power to a memory stack located above the digital device. Not requiring adding TSVs to an existing design high-performance digital device significantly reduces and/or eliminates digital device modification costs and time to manufacture new products consisting of three-dimensional stacked memory and digital device organizations. The bypass chiplets may be passive with just through conductors in silicon, or active with logic circuits therein. Flexibility of placement of the bypass chiplets in the IC layer stack in combination with an active interposer provides for many possible configurations of IC layer stacks. The digital device may be a microcontroller, a microprocessor, a PLA, an ASIC, a DSP, a GPU, a FPGA, neural processing unit, tensor processing unit, or any combination thereof.

### CROSS REFERENCE TO RELATED APPLICATION

This Application is a continuation of U.S. Non-Provisional application Ser. No. 18/526,298, filed on Dec. 11, 2023 of which is incorporated herein by reference in its entirety.

### TECHNICAL FIELD

Embodiments of the present disclosure generally relate to integrated circuit packaging of at least one digital logic/processor layer and at least one memory layer, and in particular, to configurations of digital logic/processor and memory dice arranged in a stack for use in integrated circuit packages without having to modify the digital logic/processor to supply power and control signals to the at least one memory layer.

### BACKGROUND

Memory and logic (e.g., processors and peripheral) dice, stacked and interconnected vertically, are gaining interest among memory and processor suppliers, and users to further increase memory bandwidth, reduce memory latency, reduce power required to move data and increase component integration density. Placing a stack of memory dice on top of a processor layer requires perforating the processor layer with through-silicon vias (TSV) to deliver signals and power to the memory dice located above the processor layer, which can be expensive to modify the processor layer (likely fabricated in a leading silicon processor node) and foundries might not yet be able to support or enable/offer TSVs in the leading silicon layer processor node, at least not for a while after introduction of the new silicon node.

### SUMMARY

In one example of the disclosure, an integrated circuit (IC) die stack includes at least one memory layer. A digital device. And at least one bypass chiplet, wherein the at least one memory layer is on a first side of the digital device and the at least one bypass chiplet, and power and signals pass through the at least one bypass chiplet to the at least one memory layer.

In one example of the disclosure, an integrated circuit (IC) die stack includes at least two memory layers, a digital device, and at least two bypass chiplets, wherein the at least two memory layers are on a first side of the digital device and the at least two bypass chiplets, and power and signals pass through the at least two bypass chiplets to respective ones of the at least two memory layers.

In one example of the disclosure, an integrated circuit (IC) die stack includes at least two memory layers, a digital device, and at least one bypass chiplet, wherein the at least two memory layers are on a first side of the digital device and the at least one bypass chiplet, and power and signals pass through the at least one bypass chiplet to the at least two memory layers.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a representative schematic elevational cross-section layout of a prior art memory, peripheral logic and microprocessor stack.

FIG. 2 illustrates representative schematic elevational cross-section layouts of prior art memory and processor stacks.

FIG. 3 illustrates a representative schematic elevational cross-section layout of a three-dimensional digital device/memory stack having a digital device between a memory stack and an interposer, according to an example.

FIG. 4 illustrates a representative schematic elevational cross-section layout of a three-dimensional digital device/memory stack having a digital device between a passive silicon structure and an interposer, according to an example.

FIG. 5 illustrates a representative schematic elevational cross-section layout of a three-dimensional digital device/memory stack having a digital device between a passive silicon structure and an interposer, according to another example.

FIG. 6 illustrates a representative schematic elevational cross-section layout of a three-dimensional digital device/memory stack having a digital device between a passive silicon structure and an interposer, according to yet another example.

FIGS. 7 and 8 illustrate representative schematic elevational cross-section layouts of three-dimensional digital device/memory stacks, each having a digital device between a passive silicon structure and an interposer, at least one bypass chiplet and at least two memory dice coupled to the at least one bypass chiplet, according to examples.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

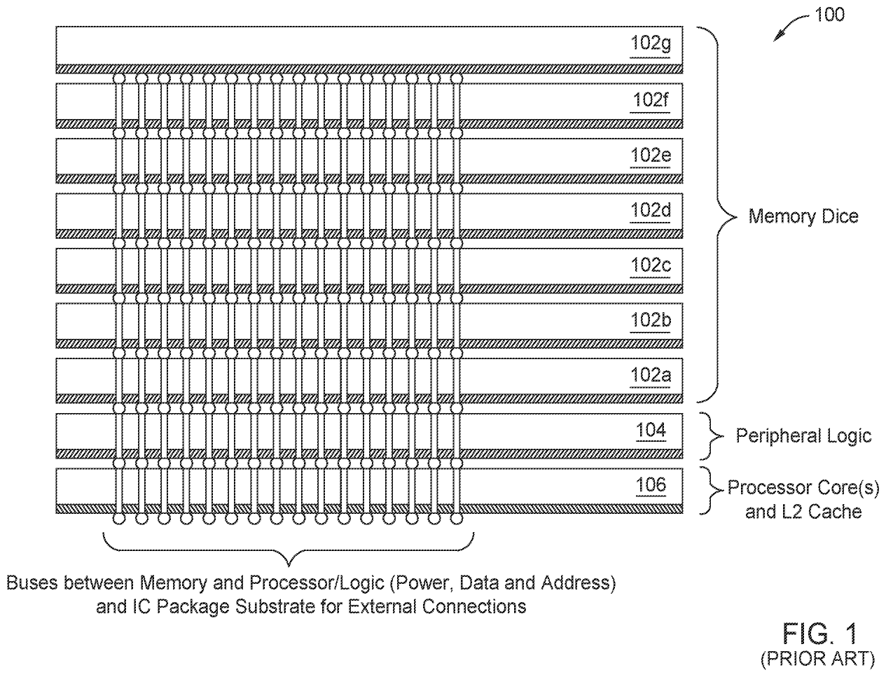

Referring to FIG. 1, depicted is a representative schematic elevational cross-section layout of a prior art memory, peripheral logic and microprocessor stack. A three-dimensional memory, e.g., dynamic random-access memory (DRAM), peripheral logic and microprocessor stack, generally represented by the numeral 100, comprises a plurality of integrated circuit (IC) semiconductor dice layered one on top of another memory dice 102, peripheral logic layer 104, and processor core(s) layer 106 vertically stacked, one above another with the processor core(s) layer 106 located at the bottom of the stack of memory dice 102. FIG. 1 depicts an example three-dimensional memory, peripheral logic and microprocessor stack 100, e.g., system on a chip (SoC), typical of present technology implementations for high capacity and speed memory, e.g., high bandwidth memory (HBM). The peripheral logic layer 104 toward the bottom may consist of circuits to the memory dice 102 and the processor core(s) layer 106. The processor core(s) layer 106 at the bottom may be electrically coupled to the peripheral logic layer 104, memory dice 102, and external IC package connections, e.g., primarily power delivery and memory interface signals (address, command, and data signals) to the memory dice 102 and peripheral logic layer 104, and may also include other circuits and connections for debug, test, control, etc., of the memory dice 102, peripheral logic layer 104 and processor core(s) layer 106. However, placing the memory dice 102 and peripheral logic layer 104 above the processor core(s) layer 106 requires perforating the processor layer with TSVs to deliver signals and power, which can be expensive to implement in the processor layer (likely fabricated in a leading silicon processor node) and might not yet be supported (foundries might not enable/offer TSVs in the leading silicon processor node, at least not for a while after introduction of the processor node).

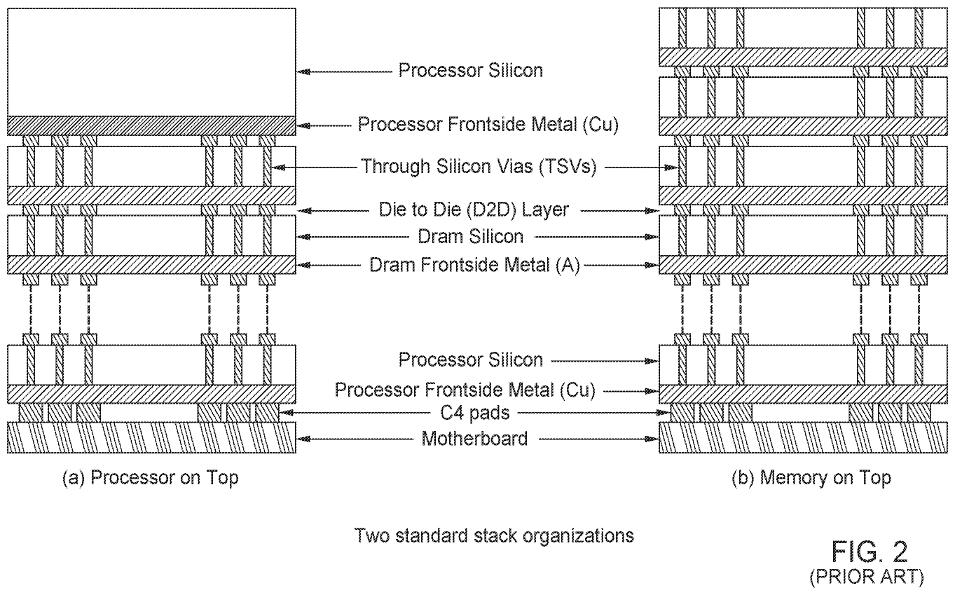

Referring to FIG. 2, depicted are representative schematic elevational cross-section layouts of prior art memory and processor stacks. In drawing (a) of FIG. 2, the processor is placed above the memory (DRAM), and power and ground are coupled to the processor with silicon vias (TSV) and microbumps that result in significant voltage (IR) drop from the motherboard to the processor. This is why present technology 3D memory/processor stacks have the processor placed closest to the printed circuit motherboard having high current lands thereon, as shown in drawing (b) of FIG. 2. But when the processor is placed closest to the printed circuit motherboard, a plurality of TSVs must be provided through a processor for signals and power to the memory layers.

According to the teachings of this disclosure, bypass chiplets are provided to avoid requiring integration of through-silicon vias (TSV) in a digital device, e.g., processor, for signals and power to a memory stack located above the digital device. Not having to add TSVs in an existing design high-performance digital device may significantly reduce and/or eliminate digital device modification costs, and time to manufacture new products consisting of three-dimensional stacked memory and digital device organizations. This also allows the usage of leading-edge digital device nodes that have not yet been enabled nor have available options for incorporating TSVs in the high-performance digital device components thereof. This allows the manufacture of advanced state of the art products using three-dimensional stacked memory and digital device configurations using existing and unmodified high-performance state of the art digital devices. A digital device may be, for example but is not limited to, one or any combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit. The terms layer, device, die, silicon layer, silicon die, and silicon device may be used interchangeable herein.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

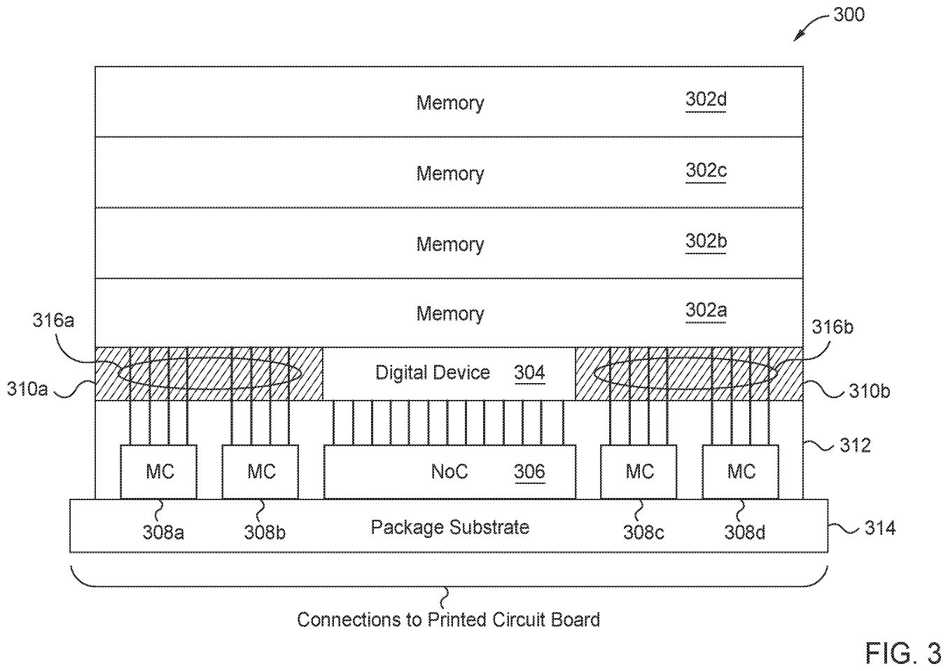

Referring to FIG. 3, depicted is a representative schematic elevational cross-section layout of a three-dimensional digital device/memory stack having a digital device between a memory stack and an interposer, according to an example. A three-dimensional digital device/memory stack, generally represented by the numeral 300, may comprise at least one layer of semiconductor memory 302, a digital device 304, at least one bypass chiplet 310 and an active interposer 312. The active interposer 312 may include at least one memory controller (MC) 308, and optionally, a data fabric/network on chip (NoC) 306. The at least one bypass chiplet 310 may be “sandwiched” between the at least one memory layer 302 and the active interposer 312, and may provide interconnections 316 (e.g., TSVs) for delivery of power and signals to the at least one memory layer 302 from the at least one MC 308.

The NoC 306 may be coupled directly to the digital device through the interposer 312. The interposer 312 may also provide interconnections between the at least one MC 308 and the NoC 306. A package substrate 314 may optionally be provided for connecting the active interposer 312 to solder lands on a printed circuit board (PCB) (not shown). The digital device 304 may also include additional logic for operation in combination with the active interposer 312. Of particular note is that the digital device 304 does not require any TSVs to be constructed through it (which might not even be feasible depending on the technology node). The bypass chiplets 310 may be manufactured in an older/more mature process node where TSVs are supported and/or are more cost effective to implement.

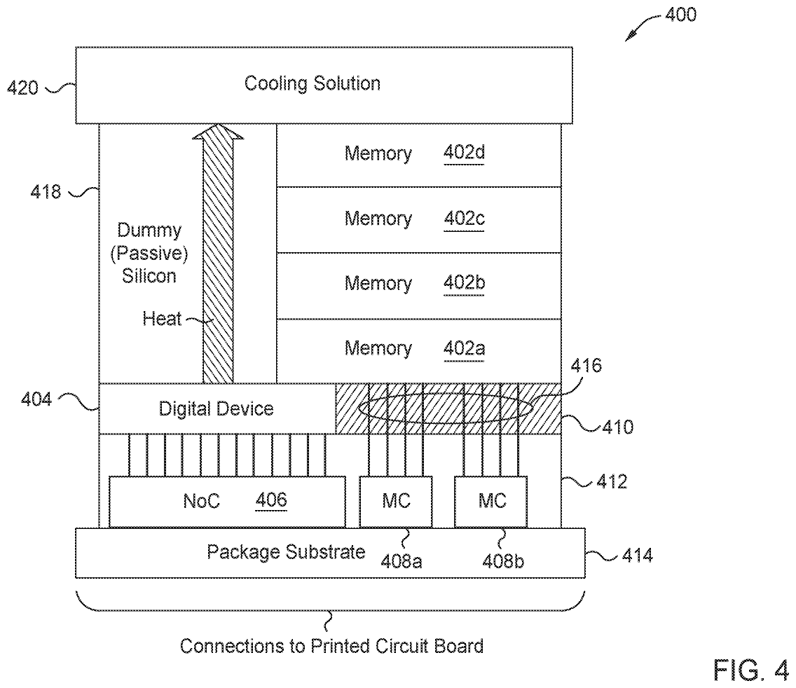

Referring to FIG. 4, depicted is a representative schematic elevational cross-section layout of a three-dimensional digital device/memory stack having a digital device between a passive silicon structure and an interposer, according to an example. A three-dimensional digital device/memory stack, generally represented by the numeral 400, may comprise at least one layer of semiconductor memory 402, a digital device 404, at least one bypass chiplet 410 and an active interposer 412. The active interposer 412 may include at least one memory controller (MC) 408, and optionally, a data fabric/network on chip (NoC) device 406. The at least one bypass chiplet 410 may be “sandwiched” between the at least one memory layer 402 and the active interposer 412, and may provide interconnections 416 (e.g., TSVs) for delivery of power and signals to the at least one memory layer 402 from the at least one MC 408. The NoC 406 may be coupled directly to the digital device through the interposer 412. The interposer 412 may also provide interconnections between the at least one MC 408 and the NoC 406. A package substrate 414 may optionally be provided for connecting the active interposer 412 to solder lands on a printed circuit board (PCB) (not shown). The digital device 404 may also include additional logic for operation in combination with the active interposer 412.

The digital device 404 is adjacent to and on the same layer as the at least one bypass chiplet 410. The digital device 404 is offset/partially overlapped from the at least one memory layer 402 above it. The interposer 412 is below the digital device 404 and the at least one bypass chiplet 410, wherein the at least one bypass chiplet 410 is between the interposer 412 and the at least one memory layer 402. Furthermore, an additional “dummy” (passive) silicon structure 418 may be located between the digital device 404 and a cooling solution 420. The cooling solution is a thermal dissipation device with heat transfer enhancement structures, for example but is not limited to, a heat sink, a heat sink with fins, liquid cooling tubes, vapor chambers, heat pipes, cold plates and the like. The silicon structure 418 provides for more effective thermal conduction pathways that have better thermal conductivity than when compared to the thermal conductivity path through the at least one memory layer 402, located above the digital device/memory stack 400, as shown in FIG. 4.

The at least one passive bypass chiplet 410 (not having active silicon/transistors) may provide electrical interconnections 416 (power and/or signals) (TSVs) to the at least one memory layer 402 from the at least one MC 408. Of particular note is that the digital device 404 does not require any electrical interconnections (TSVs) 416 to be constructed through it (which might not even be feasible depending on the technology node). The at least one bypass chiplet 410 may be manufactured in an older/more mature process node where TSVs are supported and/or are more cost effective to implement.

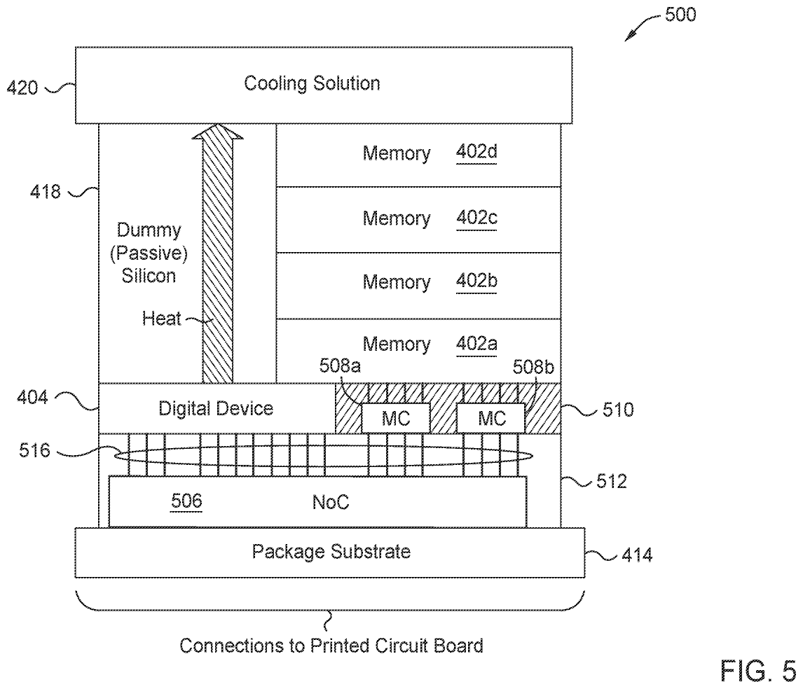

Referring to FIG. 5, depicted is a representative schematic elevational cross-section layout of a three-dimensional digital device/memory stack having a digital device between a passive silicon structure and an interposer, according to another example. A three-dimensional digital device/memory stack, generally represented by the numeral 500, may comprise at least one semiconductor memory layer 402, a digital device 404, at least one active bypass chiplet 510 and an active interposer 512. The at least one active bypass chiplet 510 may include at least one memory controller (MC) 508. The at least one bypass chiplet 510 may be “sandwiched” between the at least one memory layer 402 and the active interposer 512, and may be directly coupled to the first layer of the memory 402a for delivery of power and signals to the at least one memory layer 402 from the at least one MC 408. The active interposer 512 may, optionally, include a data fabric/network on chip (NoC) device 506. A package substrate 414 may optionally be provided for connecting the interposer 512 to solder lands on a printed circuit board (PCB) (not shown). The digital device 404 may also include additional logic for operation in combination with the active interposer 512.

The digital device 404 is adjacent to the at least one active bypass chiplet 510. The digital device 404 is adjacent to and on the same layer as the at least one active bypass chiplet 510. The digital device 404 is offset/partially overlapped from the at least one memory layer 402 above it. The interposer 512 is below the digital device 404 and the at least one active bypass chiplet 510, wherein the at least one bypass chiplet 510 is between the interposer 512 and the at least one memory layer 402. Furthermore, an additional “dummy” (passive) silicon structure 418 may be located between the digital device 404 and a cooling solution 420. The silicon structure 418 provides for more effective thermal conduction pathways that has more efficient thermal conductivity.

FIG. 5 depicts an example embodiment where the active interposer 512 implements (among other things) the NoC 506, but the memory controllers (MC) 508 are now implemented in the active bypass chiplet 510. This may provide advantages, such as reducing metal parasitic (Resistor-Capacitor) between the memory controllers (MC) 508 and the at least one memory layer 402, e.g., by shortening the data paths to only one TSV 516 length between the memory controller 508 and memory layer 402a, instead of two lengths of TSVs 516 in the prior examples hereinabove. Of particular note is that the digital device 404 does not require any electrical interconnections (TSVs) 516 to be constructed through it (which might not even be feasible depending on the technology node). The at least one active bypass chiplet 510 (with MC 508 therein) may be manufactured in an older/more mature process node where TSVs 516 are supported and/or are more cost effective to implement.

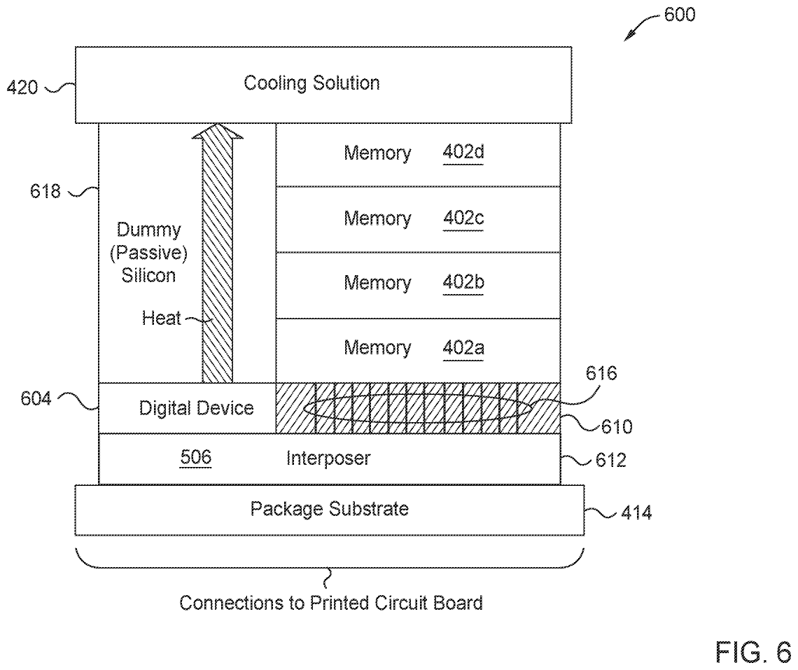

In other example embodiments, the digital device and the memory are not required to overlap (only that the memory is located at a higher level (layer) than the digital device in the sense that if this was a building, the memory would be on a higher floor or story). Referring to FIG. 6, depicted is a representative schematic elevational cross-section layout of a three-dimensional digital device/memory stack having a digital device between a passive silicon structure and an interposer, according to yet another example. A three-dimensional digital device/memory stack, generally represented by the numeral 600, may comprise at least one semiconductor memory 402, a digital device 604, at least one bypass chiplet 610 and an active interposer 612. A package substrate 414 may optionally be provided for connecting the interposer 612 to solder lands on a printed circuit board (PCB) (not shown). The digital device 604 may also include additional logic for operation in combination with the interposer 612. Furthermore, an additional “dummy” (passive) silicon structure 618 may be located between the digital device 604 and a cooling solution 420. The silicon structure 618 provides for more effective thermal conduction pathways that has more efficient thermal conductivity.

The memory 402 on top of the bypass chiplet 610 may consist of a single layer (die) of memory, or may consist of multiple layers (dice) of memory (a memory stack). As shown and described for the example embodiments hereinabove, the interposer 612 at the bottom of each digital device/memory stack is depicted as an “active interposer, e.g., comprises active logic/circuits, and electrically connected through the bypass chiplet with electrical interconnections 616 (power and/or signals) (e.g., TSVs). However, alternative example embodiments may also use passive interposers 612, so long as the circuits that would have been the active interposer's logic blocks are implemented elsewhere, e.g., in the digital device 604 and/or in an active bypass chiplet 610.

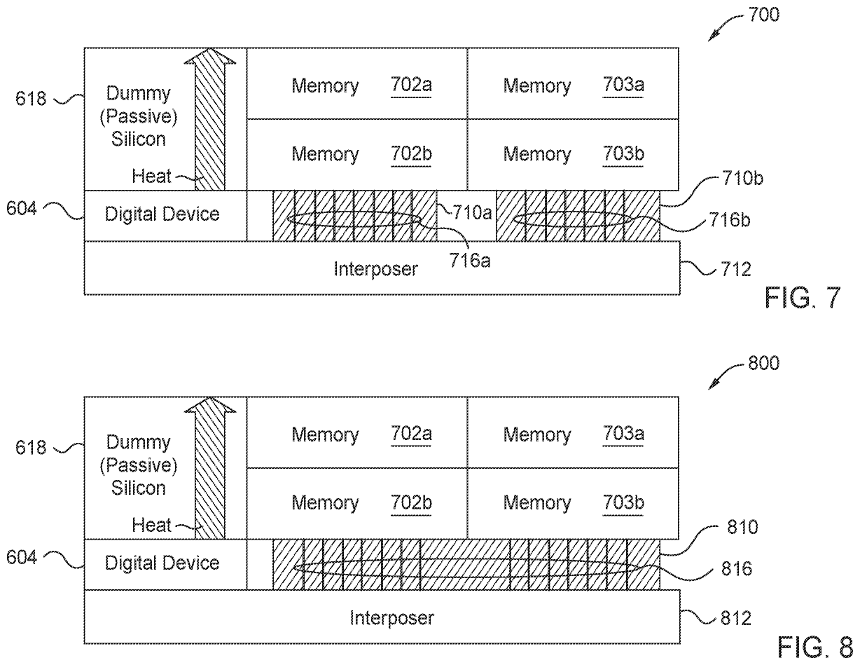

Referring to FIGS. 7 and 8, depicted are representative schematic elevational cross-section layouts of three-dimensional digital device/memory stacks, each having a digital device between a passive silicon structure and an interposer, at least one bypass chiplet and at least two memory dice coupled to the at least one bypass chiplet, according to examples. A three-dimensional digital device/memory stack, generally represented by the numeral 700, may comprise at least two semiconductor memory dice 702 and 703, a digital device 604, at least one bypass chiplet 710 and an active interposer 712. The at least one bypass chiplet 710 may be “active” or “inactive” or a combination of both. The digital device 604 may also include additional logic for operation in combination with interposer 712.

The memory 702, 703 on top of the bypass chiplets 710a and 710b may consist of a single layer (die) of memory, or may consist of multiple layers (dice) of memory (e.g., two or more memory stacks). As shown and described for the example embodiments hereinabove, the interposer 712 at the bottom of each memory stack is depicted as an “active interposer, e.g., comprises active logic/circuits, and electrically connected through the bypass chiplets 710a and 710b with electrical interconnections 716 (power and/or signals) (e.g., TSVs). However, alternative examples may also use passive interposers 712, so long as the circuits that would have been the active interposer's logic blocks are implemented elsewhere, e.g., in the digital device 604 and/or in an active bypass chiplet 710.

A three-dimensional digital device/memory stack, generally represented by the numeral 800, is similar to the aforementioned digital device/memory stack 700 with the exception that a common bypass chiplet 810 may be used in combination with electrical interconnections 816 (power and/or signals) to the memories 702 and 703. Thus, multiple memories could be placed on top of separate bypass chiplets 710a, 710b or a single bypass chiplet 810. The bypass chiplet 810 may be active or passive.

For the examples disclosed above, connections between the vias (TSVs) of the bypass chiplets, memory layer (dice), interposer, and/or digital device may be done with lower resistance metal bonding pads, e.g., hybrid-bonding, copper hybrid-bonding instead of using microbumps in the power delivery paths and may significantly lower resistance of the electrical connections. This solves a significant voltage drop problem associated with using microbumps for electrical power circuit connections. An added benefit is elimination of the die-to-die (D2D) layers between the silicon wafers, allowing direct metal-to-metal electrical connections (hybrid-bonding) between the die layers, thereby further reducing the resistance of connections there between. In addition, the layer stack thickness will be reduced and heat transfer improved there through.

In the examples disclosed hereinabove, the various semiconductor dice are illustrated or otherwise presumed to be “face down” (e.g., back end of line-BEOL metal layers facing toward the bottom of the stack, bulk silicon/backside facing upward toward the top of the stack). However, different examples may utilize one or more chiplets or other silicon components in “face up” orientations as well. It is contemplated and within the scope of this disclosure that the digital device may be located above the memory and closer to the cooling solution. The bypass chiplets disclosed herein may also be used in layer stack organizations with the memory located below the digital device.

The memory can consist of one or more memory technologies including but not limited to dynamic random-access memory (DRAM), static random-access memory (SRAM), serial shift registers, PCM, ferromagnetic RAM, spin-torque transfer RAM, spin-torque transfer STT-MRAM, eDRAM, flash RAM, phase-change memory, resistive RAM and the like. Wherein one or more memory layers may include additional functionality, such as compute or processing (e.g., processing in memory or PIM). Advantages of utilizing any one or more of the examples disclosed above avoids having to add connections (e.g., TSVs) through the digital device silicon which can increase manufacturing fabrication speed, reduce manufacturing costs and enable faster development of new products to market.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. An integrated circuit (IC) die stack, comprising:
at least one memory layer;
a digital device; and
at least one bypass chiplet, wherein the at least one memory layer is on a first side of the digital device and the at least one bypass chiplet, and power and signals pass through the at least one bypass chiplet to the at least one memory layer.

2. The IC die stack according to claim 1, further comprising an interposer coupled to the digital device and the at least one bypass chiplet, wherein the interposer is on a second side of the digital device and the at least one bypass chiplet.

3. The IC die stack according to claim 2, wherein the interposer comprises at least one memory controller electrically coupled to the at least one memory layer through the at least one bypass chiplet.

4. The IC die stack according to claim 2, wherein the interposer comprises a data fabric/network on chip (NoC) device electrically coupled to the digital device.

5. The IC die stack according to claim 1, wherein the at least one bypass chiplet comprises at least one memory controller electrically coupled to the at least one memory layer.

6. The IC die stack according to claim 1, wherein the at least one memory layer is a plurality of memory layers forming a memory stack.

7. The IC die stack according to claim 1, further comprising a passive silicon structure thermally coupled to the digital device.

8. The IC die stack according to claim 7, further comprising a cooling solution thermally coupled to the passive silicon structure and the at least one memory layer.

9. The IC die stack according to claim 2, further comprising a package substrate electrically coupled to the interposer and adapted for electrically coupling the interposer to printed circuit board connections.

10. The IC die stack according to claim 1, wherein the digital device is selected from the group consisting of any one or a combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit.

11. The IC die stack according to claim 1, wherein the at least one memory layer is selected from the group consisting of dynamic random-access memory (DRAM), static random-access memory (SRAM), serial shift registers, eDRAM, Flash, phase-change memory, resistive RAM, ferromagnetic RAM and spin-torque transfer RAM.

12. The IC die according to claim 8, wherein the cooling solution is a thermal dissipation device with heat transfer enhancement structures selected from the group consisting of a heat sink, a heat sink with fins, liquid cooling tubes, vapor chambers, heat pipes, cold plates.

13. An integrated circuit (IC) die stack, comprising:
a first at least one memory layer;
a second at least one memory layer;
a digital device; and
at least two bypass chiplets, wherein the first and second at least one memory layers are on a first side of the digital device and the at least two bypass chiplets, and power and signals pass through the at least two bypass chiplets to respective ones of the first and second at least one memory layers.

14. The IC die stack according to claim 13, further comprising an interposer coupled to the digital device and the at least two bypass chiplets, wherein the interposer is on a second side of the digital device and the at least two bypass chiplets.

15. The IC die stack according to claim 14, wherein the interposer comprises at least two memory controllers electrically coupled to respective ones of the first and second at least one memory layers through the at least two bypass chiplets.

16. The IC die stack according to claim 13, wherein each of the at least two bypass chiplets comprises at least one memory controller electrically coupled to a respective one of the first and second at least one memory layers.

17. An integrated circuit (IC) die stack, comprising:
a first at least one memory layer;
a second at least one memory layer;
a digital device; and
at least one bypass chiplet, wherein the first and second at least one memory layers are on a first side of the digital device and the at least one bypass chiplet, and power and signals pass through the at least one bypass chiplet to the first and second at least one memory layers.

18. The IC die stack according to claim 17, further comprising an interposer coupled to the digital device and the at least one bypass chiplet, wherein the interposer is on a second side of the digital device and the at least one bypass chiplet.

19. The IC die stack according to claim 18, wherein the interposer comprises at least two memory controllers electrically coupled to respective ones of the first and second at least one memory layers through the at least one bypass chiplet.

20. The IC die stack according to claim 17, wherein the at least one bypass chiplet comprises at least two memory controllers electrically coupled to respective ones of the first and second at least one memory layers.
